(19) United States
(12) Patent Application Publication
(10) Pub. No.: US 2024/0414984 A1
(43) Pub. Date: Dec. 12, 2024

(54) Display Apparatus

(71) Applicant: LG Display Co., Ltd., Seoul (KR)

(72) Inventors: Intae Ko, Daegu (KR); KwangHyun Baek, Daegu (KR)

(21) Appl. No.: 18/734,762

(22) Filed: Jun. 5, 2024

(30) Foreign Application Priority Data
Jun. 7, 2023 (KR) 10-2023-0072619

(51) Int. Cl. H10K 59/80; H10K 59/122; H10K 59/131

(52) U.S. Cl. CPC H10K 59/873; H10K 59/122; H10K 59/131

(57) ABSTRACT

A display apparatus comprises a substrate including a display area and a non-display area, a light-emitting element on the substrate in the display area, a bank on the substrate, an encapsulation layer on the light-emitting element, the encapsulation layer comprising a first inorganic encapsulation layer, an organic encapsulation layer, and a second inorganic encapsulation layer, a low-potential power line on the substrate, the low-potential power line overlapping the organic encapsulation layer, a dam on the substrate, the dam surrounding the organic encapsulation layer, and a plurality of structures at a first side of the dam and below the organic encapsulation layer, the plurality of structures comprising a first structure on the bank and a plurality of second structures on the low-potential power line, wherein an end of the first inorganic encapsulation layer and an end of the second inorganic encapsulation layer overlap an end of the substrate.

### CROSS-REFERENCE TO RELATED APPLICATION

This application claims the priority from Republic of Korea Patent Application No. 10-2023-0072619 filed on Jun. 7, 2023, which is hereby incorporated by reference in its entirety.

### BACKGROUND

### Field

The present disclosure relates to a display apparatus, and more particularly, to a display apparatus capable of having a narrow bezel.

### Description of Related Art

Recently, display apparatuses, which visually display electrical information signals, are being rapidly developed in accordance with the full-fledged entry into the information era. Various studies are being continuously conducted to develop a variety of display apparatuses which are thin and lightweight, consume low power, and have improved performance.

As the representative display apparatuses, there are a liquid crystal display (LCD) device, an electrowetting display (EWD) device, an organic light-emitting display (OLED) device, and the like.

Among the display apparatuses, the display apparatus including the organic light-emitting display device refers to a display device that autonomously emits light. Unlike a liquid crystal display device, the electroluminescent display device does not require a separate light source and thus may be manufactured as a lightweight, thin display device. In addition, the electroluminescent display device is advantageous in terms of power consumption because the electroluminescent display device operates at a low voltage. Further, the electroluminescent display device is expected to be adopted in various fields because the electroluminescent display device is also excellent in implementation of colors, response speeds, viewing angles, and contrast ratios (CRs).

### SUMMARY

An object to be achieved by the present disclosure is to provide a display apparatus capable of reducing a bezel width by scribing an inorganic encapsulation layer.

Another object to be achieved by the present disclosure is to provide a display apparatus capable of adjusting a level difference of a structure by configuring a signal line, which is disposed on a lower portion of the structure, as a plurality of sub-signal lines.

Still another object to be achieved by the present disclosure is to provide a display apparatus capable of improving a yield of the display apparatus by ensuring an inorganic encapsulation layer process margin of the display apparatus.

Yet another object to be achieved by the present disclosure is to provide a display apparatus capable of improving detection accuracy of a crack detection part.

Objects of the present disclosure are not limited to the above-mentioned objects, and other objects, which are not mentioned above, can be clearly understood by those skilled in the art from the following descriptions.

According to an embodiment of the present disclosure, there is provided a display apparatus. The display apparatus comprises a substrate comprising a display area and a non-display area, the non-display area surrounding the display area, a light-emitting element on the substrate the display area, a bank on the substrate, an encapsulation layer on the light-emitting element, the encapsulation layer comprising a first inorganic encapsulation layer, an organic encapsulation layer on the first inorganic encapsulation layer, and a second inorganic encapsulation layer on the organic encapsulation layer, a low-potential power line on the substrate, the low-potential power line overlapping the organic encapsulation layer in the non-display area, a dam on the substrate, the dam surrounding the organic encapsulation layer in the non-display area, and a plurality of structures at a first side of the dam and below the organic encapsulation layer, the plurality of structures comprising a first structure on the bank and a plurality of second structures on the low-potential power line and at the first side of the dam, wherein an end of the first inorganic encapsulation layer and an end of the second inorganic encapsulation layer overlap an end of the substrate at a second side of the dam that is opposite to the first side.

According to another embodiment of the present disclosure, there is provided a display apparatus. The display apparatus comprises a substrate comprising a display area and a non-display area, the non-display area surrounding the display area, a light-emitting element on the substrate in the display area, a bank on the substrate, an encapsulation layer on the light-emitting element, the encapsulation layer comprising a first inorganic encapsulation layer, an organic encapsulation layer on the first inorganic encapsulation layer, and a second inorganic encapsulation layer on the organic encapsulation layer, a low-potential power line outside the bank, the low-potential power line overlapping the organic encapsulation layer in the non-display area, a first structure on the bank in the non-display area, a plurality of second structures on the low-potential power line in the non-display area, and a dam outside the plurality of second structures, the dam surrounding the organic encapsulation layer in the non-display area, wherein an end of the first inorganic encapsulation layer and an end of the second inorganic encapsulation layer are aligned with an end of the substrate.

According to another embodiment of the present disclosure, there is provided a display apparatus. The display apparatus comprises a substrate including a display area and a non-display area, a light-emitting element on the display area of the substrate, a dam on the non-display area of the substrate, a low-potential power line on the non-display area of the substrate, a plurality of first structures on the low-potential power line in the non-display area and at a first side of the dam, and an encapsulation layer on the light-emitting element, the encapsulation layer including an organic encapsulation layer that overlaps the plurality of first structures and extends past an end of the plurality of first structures to the dam without extending past an end of the dam.

Other detailed matters of the embodiments of the present disclosure are included in the detailed description and the drawings.

According to the present disclosure, it is possible to reduce the bezel region of the display apparatus.

According to the present disclosure, it is possible to improve the crack detection accuracy of the display apparatus.

According to the present disclosure, it is possible to control the fluidity of the organic encapsulation layer by adjusting the level difference of the structure.

According to the present disclosure, it is possible to ensure the process margin of the inorganic encapsulation layer.

The effects according to the present disclosure are not limited to the contents exemplified above, and more various effects are included in the present disclosure.

### BRIEF DESCRIPTION OF THE DRAWINGS

The above and other embodiments, features and other advantages of the present disclosure will be more clearly understood from the following detailed description taken in conjunction with the accompanying drawings, in which:

FIG. 1 is a schematic top plan view of a display apparatus according to one or more embodiments of the present disclosure;

FIG. 2 is a cross-sectional view illustrating a subpixel of the display apparatus according to one or more embodiments of the present disclosure;

FIG. 3 is a cross-sectional view illustrating a non-display area of the display apparatus according to an embodiment of the present disclosure; and

FIG. 4 is a cross-sectional view illustrating a non-display area of a display apparatus according to another embodiment of the present disclosure.

### DETAILED DESCRIPTION

Advantages and characteristics of the present disclosure and a method of achieving the advantages and characteristics will be clear by referring to embodiments described below in detail together with the accompanying drawings. However, the present disclosure is not limited to the embodiments disclosed herein but will be implemented in various forms. The embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “comprising” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display apparatus according to embodiments of the present disclosure will be described in detail with reference to accompanying drawings.

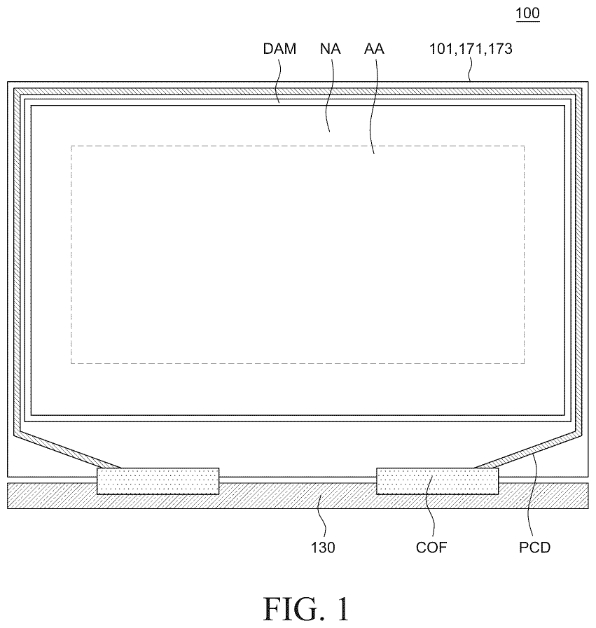

FIG. 1 is a schematic top plan view of a display apparatus according to one or more embodiment of the present disclosure. For convenience of description, FIG. 1 illustrates only a substrate 101, a plurality of flexible films COF, a printed circuit board 130, a first inorganic encapsulation layer 171, a second inorganic encapsulation layer 172, a dam DAM, and a crack detection part PCD among various constituent elements of a display apparatus 100.

The substrate 101 is a support member for supporting other components of the display apparatus 100 and may be made of an insulating material. For example, the substrate 101 may be made of glass, resin, or the like.

With reference to FIG. 1, the substrate 101 includes a display area AA and a non-display area NA.

The display area AA is an area in which images are displayed. The display area AA may include a plurality of subpixels configured to display images, and a circuit part configured to operate the plurality of subpixels. The circuit part may include various thin-film transistors, capacitors, lines, and the like for operating the subpixels. For example, the circuit part may include various constituent elements such as a drive thin-film transistor, a switching thin-film transistor, a storage capacitor, a gate line, a data line, and the like. However, the present disclosure is not limited thereto.

The non-display area NA is an area in which no image is displayed. Various lines, drive parts, and the like for operating the subpixels disposed in the display area AA are disposed in the non-display area NA.

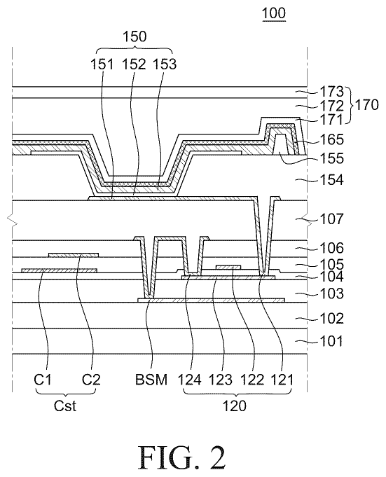

With reference to FIGS. 1 and 2, the plurality of flexible films COF is connected to one end of the substrate 101. The plurality of flexible films COF is each a film having various types of components disposed on a base film having flexibility in order to supply signals to the plurality of subpixels in the display area AA. The plurality of flexible films COF may be disposed at one end of the non-display area NA of the substrate 101 and supply data voltages or the like to the plurality of subpixels in the display area AA.

The drive parts, such as a gate drive part or a data drive part, may be disposed on the plurality of flexible films COF. A drive integrated circuit (IC) is a component configured to process data for displaying the image and process a driving signal for processing the data. The drive IC may be disposed in ways such as a chip-on-glass (COG) method, a chip-on-film (COF) method, and a tape carrier package (TCP) method depending on how the drive IC is mounted. However, the present disclosure is not limited thereto.

Meanwhile, the shapes of the plurality of flexible films COF and the number of flexible films COF, which are illustrated in FIGS. 1 and 2, are just illustrative. The flexible film COF may be variously changed in shape and number in accordance with design. However, the present disclosure is not limited thereto.

With reference to FIGS. 1 and 2, the printed circuit board 130 is connected to the plurality of flexible films COF. The printed circuit board 130 is a component for supplying a signal to the drive IC. Various types of components for supplying the drive IC with various driving signals such as driving signals, data voltages, and the like may be disposed on the printed circuit board 130.

The plurality of subpixels is disposed in the display area AA of the substrate 101. Each of the plurality of subpixels is an individual unit configured to emit light, and a light-emitting element and a drive circuit are disposed on each of the plurality of subpixels. For example, the plurality of subpixels may include a red subpixel, a green subpixel, and a blue subpixel. However, the present disclosure is not limited thereto. The plurality of subpixels may further include a white subpixel.

The encapsulation layer may be disposed on the substrate 101. The encapsulation layer may include the first inorganic encapsulation layer 171 and the second inorganic encapsulation layer 173.

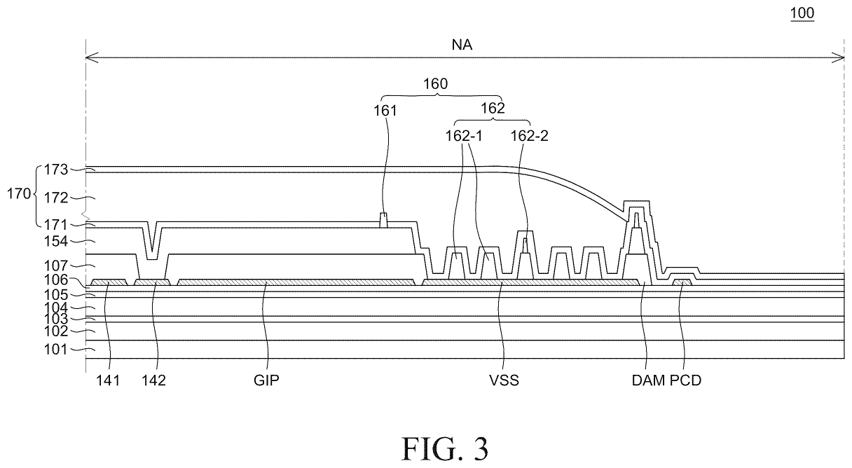

The first inorganic encapsulation layer 171 and the second inorganic encapsulation layer 173 may be disposed to cover the plurality of light-emitting elements disposed in the display area AA. The first inorganic encapsulation layer 171 and the second inorganic encapsulation layer 173 may be disposed to extend from the display area AA to the non-display area NA. In this case, an end of the first inorganic encapsulation layer 171 and an end of the second inorganic encapsulation layer 173 may overlap an end of the substrate 101. The first inorganic encapsulation layer 171 and the second inorganic encapsulation layer 173 will be described in detail with reference to FIG. 3.

The dam DAM and the crack detection part PCD may be disposed in the non-display area.

The dam DAM may be disposed to surround the organic encapsulation layer to suppress an overflow of the organic encapsulation layer.

The crack detection part PCD may be provided outside the dam DAM and disposed in the non-display area NA so as to surround the dam DAM. The crack detection part PCD may detect a crack occurring in the display apparatus 100 and be electrically connected to the flexible film COF and the printed circuit board 130.

The crack detection part PCD and the dam DAM will be described below in detail with reference to FIG. 3.

Hereinafter, the plurality of subpixels will be described in more detail with reference to FIG. 2.

FIG. 2 is a cross-sectional view illustrating the subpixel of the display panel according to one or more embodiments of the present disclosure. With reference to FIG. 2, the display apparatus 100 may include the substrate 101, first transistors 120, a storage capacitor Cst, a light-emitting element 150, and an encapsulation layer 170.

A multi-buffer layer 102 is disposed on the substrate 101. The multi-buffer layer 102 may reduce the amount of moisture or impurities penetrating through the substrate 101. The multi-buffer layer 102 may be made by alternately stacking a-Si, silicon nitride SiNx, and silicon oxide SiOx at least once.

A lower protective metal layer BSM is disposed on the substrate 101. The lower protective metal layer BSM may be disposed below the plurality of transistors 120 and minimize or at least reduce damage to the plurality of transistors 120 caused by electric charges trapped on the substrate 101.

The lower protective metal layer BSM may be configured as a single layer or multilayer made of any one or more of molybdenum (Mo), aluminum (Al), chromium (Cr), gold (Au), titanium (Ti), nickel (Ni), neodymium (Nd), and copper (Cu), or an alloy thereof. However, the present disclosure is not limited thereto.

Meanwhile, in case that the lower protective metal layer BSM is in a floating state, electric potential of the lower protective metal layer BSM may fluctuate and threshold voltages Vth of the plurality of transistors 120 may also fluctuate during an operation of the display apparatus 100. Therefore, the lower protective metal layer BSM may be disposed to be connected to a source electrode 121 or a drain electrode 124 of the plurality of transistors 120. Therefore, the lower protective metal layer BSM may be in equipotential with the source electrode 121 or the drain electrode 124, thereby minimizing or at least reducing the influence on the threshold voltage of the transistor 120.

An active buffer layer 103 is disposed on the multi-buffer layer 102 and the lower protective metal layer BSM. The active buffer layer 103 may protect the transistor 120 from impurities such as alkaline ions flowing out of the substrate 101. Further, the active buffer layer 103 may improve a bonding force between the substrate 101 and the layers formed on an upper portion of the active buffer layer 103. In addition, the active buffer layer 103 may insulate the lower protective metal layer BSM and a semiconductor layer 123. For example, the active buffer layer 103 may be configured as a single layer or multilayer made of a-Si, silicon oxide SiOx, or silicon nitride SiNx. However, the present disclosure is not limited thereto.

The transistor 120 is disposed on the active buffer layer 103. The transistor 120 may include the source electrode 121, a gate electrode 122, the semiconductor layer 123, and the drain electrode 124.

The semiconductor layer 123 may be made of any one of a polycrystalline semiconductor, an amorphous semiconductor, and an oxide semiconductor. However, the present disclosure is not limited thereto.

A gate insulation film 104 is disposed on the semiconductor layer 123. The gate insulation film 104 may be disposed on the semiconductor layer 123 and insulate the semiconductor layer 123 and the gate electrode 122. The gate insulation film 104 may be made of an insulating material such as silicon oxide SiOx or silicon nitride SiNx. In addition, the gate insulation film 104 may be made of an insulating organic material or the like.

The gate electrode 122 is disposed on the gate insulation film 104. The gate electrode 122 may be disposed to overlap the semiconductor layer 123. The gate electrode 122 may be configured as a single layer or multilayer made of any one or more of molybdenum (Mo), aluminum (Al), chromium (Cr), gold (Au), titanium (Ti), nickel (Ni), neodymium (Nd), and copper (Cu) or an alloy thereof. However, the present disclosure is not limited thereto.

A first interlayer insulation film 105 is disposed on the gate electrode 122. The first interlayer insulation film 105 may be made of an insulating material. The first interlayer insulation film 105 may be made of an insulating material such as silicon oxide SiOx or silicon nitride SiNx. In addition, the first interlayer insulation film 105 may be made of an insulating organic material or the like.

A second interlayer insulation film 106 is disposed on the first interlayer insulation film 105. The second interlayer insulation film 106 may be made of an insulating material. The second interlayer insulation film 106 may be made of an insulating material such as silicon oxide SiOx or silicon nitride SiNx. In addition, the second interlayer insulation film 106 may be made of an insulating organic material or the like.

The source electrode 121 and the drain electrode 124 may each be configured as a single layer or multilayer made of any one or more of molybdenum (Mo), aluminum (Al), chromium (Cr), gold (Au), titanium (Ti), nickel (Ni), neodymium (Nd), and copper (Cu), or an alloy thereof. However, the present disclosure is not limited thereto.

Meanwhile, the storage capacitor Cst may be disposed on the gate insulation film 104. As illustrated in FIG. 2, the storage capacitor Cst may include a storage lower electrode C1 and a storage upper electrode C2 disposed with the first interlayer insulation film 105 interposed therebetween.

The storage lower electrode C1 is disposed on the gate insulation film 104. The storage lower electrode C1 may be formed on the same layer and made of the same material as the gate electrode 122. For example, the storage lower electrode C1 may be configured as a single layer or multilayer made of any one or more of molybdenum (Mo), aluminum (Al), chromium (Cr), gold (Au), titanium (Ti), nickel (Ni), neodymium (Nd), and copper (Cu), or an alloy thereof. However, the present disclosure is not limited thereto.

The storage upper electrode C2 is disposed on the first interlayer insulation film 105. For example, the storage upper electrode C2 may be configured as a single layer or multilayer made of any one or more of molybdenum (Mo), aluminum (Al), chromium (Cr), gold (Au), titanium (Ti), nickel (Ni), neodymium (Nd), and copper (Cu), or an alloy thereof. However, the present disclosure is not limited thereto.

A planarization layer 107 is disposed on the second interlayer insulation film 106, the source electrode 121, and the drain electrode 124. The planarization layer 107 is an insulation layer for planarizing an upper portion of the substrate 101. The planarization layer 107 may be configured as a single layer or multilayer made of an organic material, for example, polyimide or photo acrylic. However, the present disclosure is not limited thereto.

The planarization layer 107 may include a contact hole for electrically connecting the transistor 120 and an anode 151. Specifically, the planarization layer 107 may include the contact hole through which any one of the source electrode 121 and the drain electrode 124 of the transistor 120 is exposed.

The light-emitting element 150 is disposed on the transistor 120. The light-emitting element 150 includes the anode 151, a light-emitting layer 152, and a cathode 153.

Meanwhile, the display apparatus 100 may be implemented as a top emission type or a bottom emission type. In the case of the top emission type, a reflective layer may be disposed on a lower portion of the anode 151 and reflect light, which is emitted from the light-emitting layer 152, toward the cathode 153. For example, the reflective layer may include a material excellent in reflectivity, such as aluminum (Al) or silver (Ag). However, the present disclosure is not limited thereto. On the contrary, in the case of the bottom emission type, the anode 151 may be made of only a transparent electrically conductive material. Hereinafter, the description will be made on the assumption that the display apparatus 100 according to the embodiment of the present disclosure is the top emission type.

The anode 151 may be disposed on the planarization layer 107. The anode 151 may correspond to each of the plurality of subpixels. That is, the anode 151 may be patterned to correspond to each of the plurality of subpixels one by one. The anode 151 may be electrically connected to the source electrode 121 of the transistor 120 through the contact hole formed in the planarization layer 107.

The anode 151 may be made of an electrically conductive material having a high work function in order to supply positive holes to the light-emitting layer 152. For example, the anode 151 may be made of a transparent electrically conductive material such as indium tin oxide (ITO) or indium zinc oxide (IZO). However, the present disclosure is not limited thereto.

A bank 154 is disposed on the anode 151 and the planarization layer 107. The bank 154 may be formed on the planarization layer 107 and cover an edge of the anode 151.

The bank 154 is an insulation layer disposed between the plurality of subpixels in order to distinguish the plurality of subpixels. The bank 154 may be disposed on the display area AA and the non-display area NA of the substrate 101. The bank 154 may be made of an organic insulating material. For example, the bank 154 may be made of polyimide-based resin, acryl-based resin, or benzocyclobutene (BCB)-based resin. However, the present disclosure is not limited thereto.

A spacer 155 may be disposed on the bank 154. The spacer 155 may suppress damage to the light-emitting element 150 that may be caused when a fine metal mask (FMM), which is used to form the light-emitting layer 152 of the light-emitting element 150, comes into direct contact with the bank 154 or the anode 151. The spacer 155 may be made of the same material as the bank 154 or made of an insulating material different from the insulating material of the bank 154. However, the present disclosure is not limited thereto. In addition, the spacer 155 and the bank 154 may be integrated at once. As the spacer 155 is disposed on the bank 154, the cathode 153 may be disposed to cover the spacer 155 and the bank 154.

The light-emitting layer 152 is disposed on the anode 151 and the bank 154. The light-emitting layer 152 may be formed over the entire surface of the substrate 101. That is, the light-emitting layer 152 may be a common layer formed in common on the plurality of subpixels. The light-emitting layer 152 may be an organic layer that emits light with a particular color. The light-emitting layer 152 may include various layers such as a hole transport layer, a hole injection layer, a hole blocking layer, an electron injection layer, an electron blocking layer, and an electron transport layer. In a tandem structure in which the plurality of light-emitting layer overlaps, a charge generating layer may be additionally disposed between the light-emitting layers.

The light-emitting layers 152 may be formed separately for the respective subpixels so that the light-emitting layers 152 in the respective subpixels emit light beams with different colors. For example, a red light-emitting layer, a green light-emitting layer, and a blue light-emitting layer may be separately formed for each of the subpixels. However, a common light-emitting layer may be formed to emit white light without distinguishing colors for each of the pixels, and color filters for distinguishing colors may be separately provided.

The cathode 153 is disposed on the light-emitting layer 152. The cathode 153 may be formed as a single layer over the entire surface of the substrate 101. That is, the cathode 153 may be a common layer formed in common in the plurality of subpixels. Because the cathode 153 supplies electrons to the light-emitting layer 152, the cathode 153 may be made of an electrically conductive material having a low work function. For example, the cathode 153 may be made of a transparent electrically conductive material such as indium tin oxide (ITO) and indium zinc oxide (IZO) or made of a metal alloy such as MgAg or an ytterbium (Yb) alloy. The cathode 153 may further include a metal doping layer. However, the present disclosure is not limited thereto.

An additional inorganic layer 165 may be disposed on the cathode 153. The additional inorganic layer 165 may be disposed between the light-emitting element 150 and the encapsulation layer 170 and inhibit moisture from penetrating into the light-emitting element 150. The additional inorganic layer 165 may be made of an inorganic material such as silicon oxide SiOx, silicon nitride SiNx, silicon oxynitride SiNxOy, or aluminum oxide AlyOz. However, the present disclosure is not limited thereto.

The encapsulation layer 170 is disposed on the light-emitting element 150. The encapsulation layer 170 protects the light-emitting element 150 from moisture or the like penetrating from the outside of the display apparatus 100. The encapsulation layer 170 includes the first inorganic encapsulation layer 171, an organic encapsulation layer 172, and the second inorganic encapsulation layer 173.

The first inorganic encapsulation layer 171 may be disposed on the cathode 153 and suppress the penetration of moisture or oxygen. The first inorganic encapsulation layer 171 may be made of an inorganic material such as silicon oxide SiOx, silicon nitride SiNx, silicon oxynitride SiNxOy, or aluminum oxide AlyOz. However, the present disclosure is not limited thereto.

The organic encapsulation layer 172 is disposed on the first inorganic encapsulation layer 171 and planarizes a surface of the first inorganic encapsulation layer 171. In addition, the organic encapsulation layer 172 may cover foreign substances or particles that may be produced during the manufacturing process. The organic encapsulation layer 172 may be made of an organic material, for example, silicon oxycarbon SiOxCz or acrylic or epoxy-based resin. However, the present disclosure is not limited thereto.

Like the first inorganic encapsulation layer 171, the second inorganic encapsulation layer 173 may be disposed on the organic encapsulation layer 172 and inhibit the penetration of moisture or oxygen. In this case, the second inorganic encapsulation layer 173 and the first inorganic encapsulation layer 171 may be formed to seal the organic encapsulation layer 172. Therefore, the second inorganic encapsulation layer 173 may more effectively reduce the amount of moisture or oxygen penetrating into the light-emitting element 150. The second inorganic encapsulation layer 173 may be made of an inorganic material such as silicon oxide SiOx, silicon nitride SiNx, silicon oxynitride SiNxOy, or aluminum oxide AlyOz. However, the present disclosure is not limited thereto.

FIG. 3 is a cross-sectional view illustrating the non-display area of the display apparatus according to an embodiment of the present disclosure.

With reference to FIG. 3, the substrate 101, the multi-buffer layer 102, the active buffer layer 103, the gate insulation film 104, the first interlayer insulation film 105, the second interlayer insulation film 106, the planarization layer 107, the bank 154, the encapsulation layer 170, a first metal layer 141, a second metal layer 142, a gate drive part GIP, a low-potential power line VSS, the dam DAM, the crack detection part PCD, and a plurality of structures 160 may be disposed in the non-display area NA.

The first metal layer 141, the second metal layer 142, the gate drive part GIP, the low-potential power line VSS, and the crack detection part PCD may be disposed on the second interlayer insulation film 106.

The first metal layer 141 may be disposed in the non-display area NA. The first metal layer 141 may be disposed to extend from the display area AA. For example, the first metal layer 141 may be a line connected to the light-emitting element 150 disposed in the display area AA.

The first metal layer 141 may be made of the same material as the source electrode 121 or the drain electrode 124. For example, the first metal layer 141 may be configured as a single layer or multilayer made of any one or more of molybdenum (Mo), aluminum (Al), chromium (Cr), gold (Au), titanium (Ti), nickel (Ni), neodymium (Nd), and copper (Cu), or an alloy thereof. However, the present disclosure is not limited thereto.

The second metal layer 142 may be disposed outside the first metal layer 141.

The second metal layer 142 may be disposed outside the display area AA and adjoin the bank 154. The planarization layer 107 may be partially removed from the non-display area NA to inhibit oxygen and moisture from penetrating into the display area AA. In this case, the second metal layer 142 may be disposed to reduce a degree to which a physical impact is applied to the layer disposed below the planarization layer 107 during a process of removing the planarization layer 107. Therefore, the second metal layer 142 may be disposed to overlap an area from which the planarization layer 107 is removed. The second metal layer 142 may be disposed to adjoin the bank 154 disposed on an upper portion of the planarization layer 107.

The second metal layer 142 may be made of the same material as the source electrode 121 or the drain electrode 124. For example, the second metal layer 142 may be configured as a single layer or multilayer made of any one or more of molybdenum (Mo), aluminum (Al), chromium (Cr), gold (Au), titanium (Ti), nickel (Ni), neodymium (Nd), and copper (Cu), or an alloy thereof. However, the present disclosure is not limited thereto.

The gate drive part GIP may be disposed outside the first metal layer 141 and the second metal layer 142. The gate drive part GIP may supply a display area DA with a gate drive voltage supplied through a gate pad. FIG. 3 illustrates that the gate drive part GIP is made of the same material as the source electrode 121 or the drain electrode 124, but this configuration is provided merely for convenience of illustration. The gate drive part GIP may include the transistor 120, capacitors, and/or the like.

The low-potential power line VSS may be disposed outside the gate drive part GIP. The low-potential power line VSS may be provided between the gate drive part GIP and the display area AA and disposed to surround an outer peripheral area of the substrate 101. The low-potential power line VSS may be disposed to overlap the organic encapsulation layer 172 in the outer peripheral area of the substrate 101.

The low-potential power line VSS may be made of the same material as the source electrode 121 or the drain electrode 124. For example, the low-potential power line VSS may be configured as a single layer or multilayer made of any one or more of molybdenum (Mo), aluminum (Al), chromium (Cr), gold (Au), titanium (Ti), nickel (Ni), neodymium (Nd), and copper (Cu), or an alloy thereof. However, the present disclosure is not limited thereto.

The crack detection part PCD may be provided on the substrate 101 and disposed outside the gate drive part GIP.

The crack detection part PCD may be disposed in the non-display area NA disposed outside the dam DAM and surround the dam DAM. The crack detection part PCD may be disposed to surround the low-potential power line VSS. A portion of the dam DAM may overlap the low-potential power line VSS.

The crack detection part PCD may be made of the same material as the source electrode 121 or the drain electrode 124. For example, the crack detection part PCD may be configured as a single layer or multilayer made of any one or more of molybdenum (Mo), aluminum (Al), chromium (Cr), gold (Au), titanium (Ti), nickel (Ni), neodymium (Nd), and copper (Cu), or an alloy thereof. However, the present disclosure is not limited thereto.

The planarization layer 107, the bank 154, and the encapsulation layer 170 may be disposed on the first metal layer 141, the second metal layer 142, and the gate drive part GIP.

The plurality of structures 160 may be disposed to overlap the bank 154 and the low-potential power line VSS. The plurality of structures 160 may be disposed to be closer to the display area AA than the dam DAM, which is disposed in the outer peripheral area of the substrate 101, to the display area AA. That is, the plurality of structures 160 may be disposed at a first side of the dam DAM and disposed below the organic encapsulation layer 172. A height of the dam DAM may be greater than a height of each of the plurality of structures 160.

The plurality of structures 160 may include a first structure 161 disposed on the bank 154, and a plurality of second structures 162 disposed on the low-potential power line VSS in the non-display area NA and at the first side of the dam DAM. The organic encapsulation layer 172 may overlap the plurality of second structures 162 and extend past an end of the plurality of second structures 162 to the dam DAM without extending past an end of the dam DAM. Additionally, the organic encapsulation layer 172 may overlap the first structure 161 and extend past an end of the first structure 161.

The first structure 161 may be disposed inward of the plurality of second structures 162. For example, as illustrated in FIG. 3, among the plurality of structures 160, the first structure 161 may be disposed to be closer to the display area AA than the plurality of second structures 162 to the display area AA. The plurality of second structures 162 may be disposed outward of the first structure 161 and disposed adjacent to the outer periphery of the substrate 101.

A height of the first structure 161 may be different from a height of each of the plurality of second structures 162. For example, the first structure 161 may have a greater height than a height of the second structure 162, and the height of the first structure 161 may be greater than the height of each of the plurality of second structures 162. As illustrated in FIG. 3, the first structure 161 may be disposed on the bank 154, and the second structures 162 may be disposed on the low-potential power line VSS. However, the present disclosure is not limited thereto.

The first structure 161 and the plurality of second structures 162 may be made of a material identical to the material disposed in the display area AA. For example, the first structure 161 may be made of the same material as the spacer 155, and the plurality of second structures 162 may be made of the same material as the spacer 155 and the bank 154. However, the present disclosure is not limited thereto.

The plurality of second structures 162 may be between the first structure 161 and the dam DAM. The plurality of second structures 162 may include a plurality of first sub-structures 162-1 and a second sub-structure 162-2 disposed between the plurality of first sub-structures 162-1.

A height of each of the plurality of first sub-structures 162-1 may be different from a height of the second sub-structure 162-2. For example, the second sub-structure 162-2 may have a structure comprising the first sub-structure 162-1 and an additional layer stacked on the first sub-structure 162-1. As illustrated in FIG. 3, the first sub-structure 162-1 may be made of the same material as the planarization layer 107, and the second sub-structure 162-2 may be made of the same material as the planarization layer 107 and the bank 154.

In addition, a width of each of the plurality of first sub-structures 162-1 may be different from a width of the second sub-structure 162-2. In this case, the width of the first sub-structure 162-1 and the width of the second sub-structure 162-2 may refer to a width of a bottom surface of the first sub-structure 162-1, which overlaps the substrate 101, and a width of a bottom surface of the second sub-structure 162-2 that overlaps the substrate 101.

The width of the second sub-structure 162-2 may be larger than the width of the first sub-structure 162-1. For example, the width of the first sub-structure 162-1 may be 16 μm, and the width of the second sub-structure 162-2 may be 50 μm.

Meanwhile, a spacing interval between the plurality of first sub-structures 162-1 may be equal to a spacing interval between the second sub-structure 162-2 and the first sub-structure 162-1 adjacent to the second sub-structure 162-2. For example, the plurality of first sub-structures 162-1 may be disposed to be spaced apart from one another by the width of each of the first sub-structures 162-1. In this case, in case that the width of the first sub-structure 162-1 is 16 μm, the interval between the adjacent first sub-structures 162-1 may be 16 μm, and the interval between the second sub-structure 162-2 and the first sub-structure 162-1 adjacent to the second sub-structure 162-2 may also be 16 μm.

The dam DAM may be disposed outside the plurality of structures 160. The dam DAM may be disposed to surround the organic encapsulation layer 172 to suppress an overflow of the organic encapsulation layer 172.

The dam DAM may be disposed to overlap the low-potential power line VSS. For example, the dam DAM may be disposed to cover an end of the low-potential power line VSS. Therefore, the dam DAM may adjoin a top surface of the low-potential power line VSS, and the dam DAM may be disposed outside the low-potential power line VSS and adjoin the first interlayer insulation film 105 on the substrate 101. However, the present disclosure is not limited thereto.

As illustrated in FIG. 3, the dam DAM may include a plurality of layers. In this case, the dam DAM may be made of a material identical to the material disposed in the display area AA. For example, the dam DAM may be made of the same material as the spacer 155, the bank 154, and the planarization layer 107. However, the present disclosure is not limited thereto.

Meanwhile, a height of the dam DAM may be greater than a height of the first sub-structure 162-1. Therefore, the dam DAM may more efficiently suppress an overflow of the organic encapsulation layer.

The encapsulation layer 170 may be disposed on the bank 154, the plurality of structures 160, and the dam DAM.

The first inorganic encapsulation layer 171 may be disposed to extend from the display area AA to the non-display area NA. In this case, the first inorganic encapsulation layer 171 may be disposed outside the dam DAM and adjoin (i.e., is in contact with) the crack detection part PCD. In addition, with reference to FIG. 3, an end of the first inorganic encapsulation layer 171 may overlap an end of the substrate 101 at a second side of the dam DAM that is opposite to the first side of the dam DAM. In other words, the end of the first inorganic encapsulation layer 171 may be aligned with the end of the substrate 101 at the second side of the dam DAM. The first inorganic encapsulation layer 171 may overlap the plurality of second structures 162 and the dam DAM and extend past an end of the dam DAM.

The organic encapsulation layer 172 is disposed on the first inorganic encapsulation layer 171 and disposed in the display area AA and a part of the non-display area NA extending from the display area AA. For example, the organic encapsulation layer 172 may be disposed at the first side of the dam DAM. The organic encapsulation layer may surround each of the plurality of second structures 162.

The second inorganic encapsulation layer 173 may be disposed to extend from the display area AA to the non-display area NA. The second inorganic encapsulation layer 173 may be disposed outside an end of the organic encapsulation layer 172 and adjoin the first inorganic encapsulation layer 171. For example, the second inorganic encapsulation layer 173 may be disposed outside the dam DAM and adjoin the first inorganic encapsulation layer 171. The third inorganic encapsulation layer 173 may overlap the plurality of second structures 162 and the dam DAM and extend past the end of the dam DAM.

In this case, the second inorganic encapsulation layer 173 may be disposed outside the dam DAM and overlap the crack detection part PCD. Therefore, the first inorganic encapsulation layer 171 and the second inorganic encapsulation layer 173 may be disposed to cover side surfaces of the crack detection part PCD and a top surface of the crack detection part PCD. In addition, with reference to FIG. 3, an end of the second inorganic encapsulation layer 173 may overlap the end of the substrate 101 at the second side of the dam DAM. In other words, the end of the first inorganic encapsulation layer 171 may be aligned with the end of the substrate 101 at the second side of the dam DAM. The crack detection part PCD may be on the non-display area NA of the substrate 101 at the second side of the dam DAM. The first inorganic encapsulation layer 171 and the third inorganic encapsulation layer 173 may overlap the crack detection part PCD without the organic encapsulation layer 172 overlapping the crack detection part PCD.

The non-display area of the display apparatus, except for the display area in which images are displayed, is required to be reduced to meet the demand for the slim display apparatus. Meanwhile, a process of cutting the substrate from the outside of the inorganic layer is performed to inhibit the occurrence and propagation of cracks in the inorganic layer during a process of cutting the substrate of the display apparatus into a display panel size. For example, a process of cutting the substrate from the outside of the first and second inorganic encapsulation layers disposed on the substrate is performed.

Meanwhile, in case that the cutting process is performed at a point spaced apart from the ends of the first and second inorganic encapsulation layers by a significant distance, an area in which the cutting process is performed is restricted, which causes a limitation in reducing the bezel of the display apparatus.

In addition, in case that the substrate is made of an organic material, the substrate may be inadvertently moved by an external force during the cutting process, which causes a high risk that the substrate cracks and by-products, which are produced during the cutting process, propagate into the display apparatus.

Therefore, the display apparatus 100 according to the embodiment of the present disclosure is manufactured by the process of cutting the first inorganic encapsulation layer 171 and the second inorganic encapsulation layer 173 together with the substrate 101, such that the end of the substrate and the ends of the first and second inorganic encapsulation layers may be consistent with one another. Therefore, the size of the display panel may be designed regardless of the process margins of the first and second inorganic encapsulation layers 171 and 173. Therefore, the process of manufacturing the display apparatus may be performed while ignoring the process margins of the first and second inorganic encapsulation layers 171 and 173, such that the yield of the display apparatus 100 may be improved. In addition, a sufficient margin may be ensured in the process of cutting an outer peripheral portion of the display apparatus 100, such that the size of the non-display area NA of the display apparatus 100 may be reduced, which may implement a narrow bezel.

In addition, the display apparatus 100 according to the embodiment of the present disclosure may include the plurality of structures 160 disposed to be closer to the display area AA than the dam DAM, which is disposed in the outer peripheral area of the substrate 101, to the display area AA. First, it is possible to control the shape of the organic encapsulation layer 172 in an area, in which the top surface of the organic encapsulation layer 172 is adjacent to the non-display area NA and the display area AA, by disposing the first structure 161 having the highest height so that the first structure 161 having the highest height is adjacent to the display area AA. Next, the second structures 162 disposed on the low-potential power line VSS is configured such that the plurality of first sub-structures 162-1 and the second sub-structure 162-2, which have different heights, are alternately arranged in the non-display area NA, such that the organic encapsulation layer 172 may be dispersed to spaces defined between the plurality of first sub-structures 162-1 and the second sub-structure 162-2, thereby minimizing or at least reducing the amount of the organic encapsulation layer 172 propagating to the outer peripheral portion of the display apparatus 100. Therefore, the plurality of structures 160 of the display apparatus 100 according to the embodiment of the present disclosure may minimize or at least reduce the amount of the organic encapsulation layer 172 propagating to the outer peripheral portion of the display apparatus 100, such that the size of the non-display area NA of the display apparatus 100 may feature the narrow bezel.

In addition, in the display apparatus 100 according to the embodiment of the present disclosure, the substrate 101 made of glass is used, which may reduce a likelihood that the first inorganic encapsulation layer 171 and the second inorganic encapsulation layer 173 are separated or damaged. In case that the substrate 101 made of glass is cut, the rigidity of the substrate 101 may be increased, and the amount of inadvertent movement of the substrate 101 caused by an external force during the cutting process may be small. Therefore, it is possible to reduce a risk of the occurrence of cracks and a risk of the propagation of the by-products into the display apparatus 100. Therefore, even though the first inorganic encapsulation layer 171 and the second inorganic encapsulation layer 173 are cut together with the substrate 101, it is possible to reduce a likelihood that the first and second inorganic encapsulation layers 171 and 173 are cracked or the crack propagates, thereby ensuring the process stability.

In addition, in the display apparatus 100 according to the embodiment of the present disclosure, the first inorganic encapsulation layer 171 and the second inorganic encapsulation layer 173 may be disposed to cover the top and side surfaces of the crack detection part PCD, thereby improving the reliability of the crack detection part PCD. In case that the organic material is disposed on the crack detection part PCD, the organic material may absorb an impact applied to the crack detection part PCD, which may degrade the sensitivity and reliability of the crack detection part PCD. Therefore, in the display apparatus 100 according to the embodiment of the present disclosure, the first and second inorganic encapsulation layers 171 and 173, which are made of an inorganic material, cover the crack detection part PCD, which may improve the sensitivity and detection reliability of the crack detection part PCD.

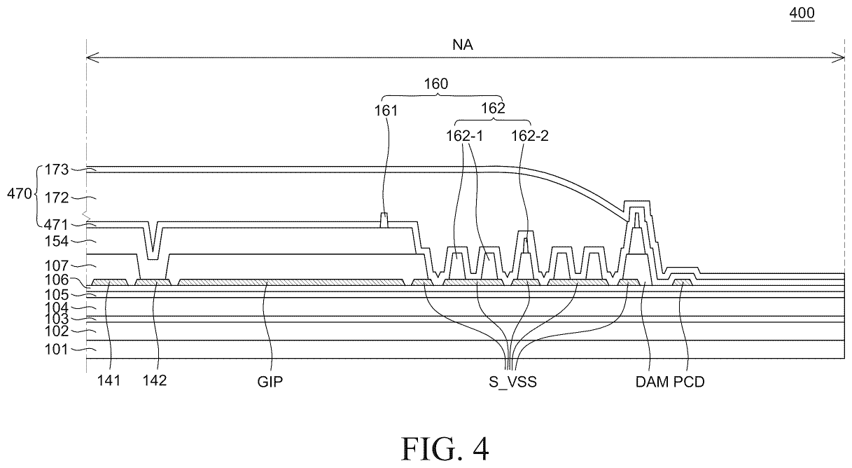

FIG. 4 is a cross-sectional view illustrating a non-display area of a display apparatus according to another embodiment of the present disclosure. Because a display apparatus 400 according to another embodiment of the present disclosure is substantially identical in configuration to the display apparatus 100 according to the embodiment of the present disclosure, except for a plurality of sub-low-potential power lines S_VSS and an encapsulation layer 470, a repeated description will be omitted.

A low-potential line may be disposed outside the gate drive part GIP and include the plurality of sub-low-potential power lines S_VSS spaced apart from one another. The plurality of sub-low-potential power lines S_VSS may each be disposed between the gate drive part GIP and the display area AA and surround the outer peripheral area of the substrate 101.

The plurality of sub-low-potential power lines S_VSS may be made of the same material as the source electrode 121 or the drain electrode 124. For example, the plurality of sub-low-potential power lines S_VSS may each be configured as a single layer or multilayer made of any one or more of molybdenum (Mo), aluminum (Al), chromium (Cr), gold (Au), titanium (Ti), nickel (Ni), neodymium (Nd), and copper (Cu), or an alloy thereof. However, the present disclosure is not limited thereto.

The plurality of sub-low-potential power lines S_VSS may be disposed to overlap the plurality of structures 160. For example, the plurality of sub-low-potential power lines S_VSS may be disposed below the plurality of second structures 162 and overlap the plurality of second structures 162. In this case, the plurality of sub-low-potential power lines S_VSS may be disposed to respectively overlap the plurality of first sub-structures 162-1 and the second sub-structure 162-2. The plurality of sub-low-potential power lines S_VSS may be disposed between the plurality of first sub-structures 162-1 and the second sub-structure 162-2 and spaced apart from one another.

For example, as illustrated in FIG. 4, in case that two first sub-structures 162-1 are disposed between the second sub-structures 162-2, the plurality of sub-low-potential power lines S_VSS may be disposed to respectively overlap the two first sub-structures 162-1.

The plurality of structures 160 including the first structure 161 and the plurality of second structures 162 may be disposed to overlap the bank 154 and the plurality of sub-low-potential power lines S_VSS.

The plurality of second structures 162 may be disposed on the plurality of sub-low-potential power lines S_VSS.

The encapsulation layer 470 including a first inorganic encapsulation layer 471, the organic encapsulation layer 172, and the second inorganic encapsulation layer 173 may be disposed on the bank 154, the plurality of structures 160, and the dam DAM.

The first inorganic encapsulation layer 471 may be disposed along shapes of the plurality of structures 160 and shapes of the plurality of sub-low-potential power lines S_VSS. Therefore, the first inorganic encapsulation layer 471 may be disposed between the plurality of sub-low-potential power lines S_VSS and cover side surfaces of the plurality of sub-low-potential power lines S_VSS.

The organic encapsulation layer 172 may be disposed on the first inorganic encapsulation layer 471 and fill a top surface of the first inorganic encapsulation layer 471 curved along the shapes of the plurality of structures 160 and along the shapes of the plurality of sub-low-potential power lines S_VSS.

The second inorganic encapsulation layer 173 may be disposed on the organic encapsulation layer 172. The second inorganic encapsulation layer 173 may be disposed outside an end of the organic encapsulation layer 172 and adjoin the first inorganic encapsulation layer 171.

Therefore, in the display apparatus 400 according to another embodiment of the present disclosure, the size of the display panel may be ensured by cutting the first inorganic encapsulation layer 471 and the second inorganic encapsulation layer 173, such that the size of the display panel may be designed regardless of the areas of the first and second inorganic encapsulation layers 471 and 173, which may reduce the size of the non-display area NA of the display apparatus 400 and implement the narrow bezel.

In addition, in the display apparatus 400 according to another embodiment of the present disclosure, the plurality of structures 160 may minimize or at least reduce the amount of the organic encapsulation layer 172 propagating to the outer peripheral portion of the display apparatus 400, and the size of the non-display area NA of the display apparatus 400 may be reduced, which may implement the narrow bezel.

In addition, in the display apparatus 400 according to another embodiment of the present disclosure, the substrate 101 made of glass may be used. Therefore, even though the first inorganic encapsulation layer 471 and the second inorganic encapsulation layer 173 are cut together with the substrate 101, it is possible to reduce a likelihood that the first and second inorganic encapsulation layers 471 and 173 are cracked or the crack propagates, thereby ensuring the process stability.

In addition, in the display apparatus 400 according to another embodiment of the present disclosure, the first inorganic encapsulation layer 471 and the second inorganic encapsulation layer 173 may be disposed to cover the top and side surfaces of the crack detection part PCD, thereby improving the reliability of the crack detection part PCD.

In addition, in the display apparatus 400 according to another embodiment of the present disclosure, the plurality of sub-low-potential power lines S_VSS is disposed between the plurality of first sub-structures 162-1 and the second sub-structure 162-2 and spaced apart from one another, which may minimize or at least reduce the amount of the organic encapsulation layer 172 propagating to the outer peripheral portion of the display apparatus 400. In case that the plurality of sub-low-potential power lines S_VSS is disposed between the plurality of first sub-structures 162-1 and the second sub-structure 162-2 and spaced apart from one another, the first inorganic encapsulation layer 471 may cover the side surfaces of the plurality of sub-low-potential power lines S_VSS exposed between the plurality of first sub-structures 162-1 and the second sub-structure 162-2. That is, the first inorganic encapsulation layer 471 may have level differences corresponding to the heights of the plurality of first sub-structures 162-1, the height of the second sub-structure 162-2, and the heights of the plurality of sub-low-potential power lines S_VSS. Therefore, the organic encapsulation layer 172 may be dispersed to the spaces between the plurality of first sub-structures 162-1 and the second sub-structure 162-2 and the spaces between the plurality of sub-low-potential power lines S_VSS. Therefore, the amount of the organic encapsulation layer 172 propagating to the outer peripheral portion of the display apparatus 400 may be minimized or at least reduced, which may reduce the size of the non-display area NA of the display apparatus 400.

The embodiments of the present disclosure can also be described as follows:

According to an embodiment of the present disclosure, there is provided a display apparatus. The display apparatus comprises a substrate made of glass and comprising a display area and a non-display area configured to surround the display area, a light-emitting element disposed in the display area on the substrate, a bank disposed on the substrate and configured to define a light-emitting area and a non-light-emitting area, an encapsulation layer disposed on the light-emitting element and comprising a first inorganic encapsulation layer, an organic encapsulation layer on the first inorganic encapsulation layer, and a second inorganic encapsulation layer on the organic encapsulation layer, a low-potential power line disposed on the substrate and disposed to overlap the organic encapsulation layer, a dam disposed on the substrate and configured to surround the organic encapsulation layer and a plurality of structures disposed inside the dam and disposed below the organic encapsulation layer, wherein an end of the first inorganic encapsulation layer and an end of the second inorganic encapsulation layer overlap an end of the substrate, and wherein the plurality of structures comprises a first structure disposed on the bank and a plurality of second structures disposed on the low-potential power line.

A height of the first structure may be different from a height of each of the plurality of second structures.

The height of the first structure may be higher than the height of each of the plurality of second structures.

The first structure may be disposed inward of the plurality of second structures.

The display apparatus may further comprise a crack detection part disposed on the substrate and configured to surround the dam, wherein the first inorganic encapsulation layer and the second inorganic encapsulation layer may cover side and top surfaces of the crack detection part.

The first inorganic encapsulation layer may adjoin the crack detection part.

The dam may cover an end of the low-potential power line.

The plurality of second structures may comprise a plurality of first sub-structures and a second sub-structure disposed between the plurality of first sub-structures, and wherein a height of each of the plurality of first sub-structures may be different from a height of the second sub-structure.

A height of the dam may be higher than a height of the first sub-structure.

The low-potential power line may comprise a plurality of sub-low-potential power lines spaced apart from one another, and the plurality of second structures may be disposed on the plurality of sub-low-potential power lines.

The first inorganic encapsulation layer may be disposed between the plurality of sub-low-potential power lines and covers side surfaces of the plurality of sub-low-potential power lines.

The display apparatus may further comprise a spacer disposed on the bank and a planarization layer disposed below the light-emitting element, wherein the first structure may be made of the same material as the spacer, wherein the plurality of second structures may be made of the same material as the spacer and the bank, and wherein the dam may be made of the same material as the spacer, the bank, and the planarization layer.

According to another embodiment of the present disclosure, there is provided a display apparatus. The display apparatus comprises a substrate made of glass and comprising a display area and a non-display area configured to surround the display area, a light-emitting element disposed in the display area on the substrate, a bank disposed on the substrate and configured to define a light-emitting area and a non-light-emitting area, an encapsulation layer disposed on the light-emitting element and comprising a first inorganic encapsulation layer, an organic encapsulation layer on the first inorganic encapsulation layer, and a second inorganic encapsulation layer on the organic encapsulation layer, a low-potential power line disposed outside the bank and disposed to overlap the organic encapsulation layer, a first structure disposed on the bank, a plurality of second structures disposed on the low-potential power line and a dam disposed outside the plurality of second plurality of structures and configured to surround the organic encapsulation layer, wherein an end of the first inorganic encapsulation layer and an end of the second inorganic encapsulation layer are disposed on the same plane as an end of the substrate.

The display apparatus may further comprise a crack detection part disposed to surround the low-potential power line on the substrate, wherein the first inorganic encapsulation layer adjoins the crack detection part.

The dam may be disposed to overlap an end of the low-potential power line.

The plurality of second structures may comprise a plurality of first sub-structures and a second sub-structure that may have different heights, and the plurality of first sub-structures and the second sub-structure may be alternately disposed.

The second sub-structure may have a structure comprising the first sub-structure and an additional layer stacked on the first sub-structure.

The low-potential power line may comprise a plurality of sub-low-potential power lines spaced apart from one another, and the plurality of sub-low-potential power lines may be disposed between the plurality of first sub-structures and the second sub-structure and spaced apart from one another.

The first inorganic encapsulation layer may be disposed between the plurality of first sub-structures and the second sub-structure and cover side surfaces of the plurality of sub-low-potential power lines.

Although the embodiments of the present disclosure have been described in detail with reference to the accompanying drawings, the present disclosure is not limited thereto and may be embodied in many different forms without departing from the technical concept of the present disclosure. Therefore, the embodiments of the present disclosure are provided for illustrative purposes only but not intended to limit the technical concept of the present disclosure. The scope of the technical concept of the present disclosure is not limited thereto. Therefore, it should be understood that the above-described embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display apparatus, comprising:
a substrate comprising a display area and a non-display area, the non-display area surrounding the display area;
a light-emitting element on the substrate in the display area;
a bank on the substrate;
an encapsulation layer on the light-emitting element, the encapsulation layer comprising a first inorganic encapsulation layer, an organic encapsulation layer on the first inorganic encapsulation layer, and a second inorganic encapsulation layer on the organic encapsulation layer;
a low-potential power line on the substrate, the low-potential power line overlapping the organic encapsulation layer in the non-display area;
a dam on the substrate, the dam surrounding the organic encapsulation layer in the non-display area; and
a plurality of structures at a first side of the dam and below the organic encapsulation layer, the plurality of structures comprising a first structure on the bank and a plurality of second structures on the low-potential power line and at the first side of the dam,
wherein an end of the first inorganic encapsulation layer and an end of the second inorganic encapsulation layer overlap an end of the substrate at a second side of the dam that is opposite to the first side.

2. The display apparatus of claim 1, wherein a height of the first structure is different from a height of each of the plurality of second structures.

3. The display apparatus of claim 2, wherein the height of the first structure is greater than the height of each of the plurality of second structures.

4. The display apparatus of claim 1, wherein the first structure is closer to the display area than the plurality of second structures.

5. The display apparatus of claim 1, further comprising:
a crack detection part on the substrate in the non-display area, the crack detection part surrounding the dam,
wherein the first inorganic encapsulation layer and the second inorganic encapsulation layer cover side surfaces of the crack detection part and a top surface of the crack detection part.

6. The display apparatus of claim 5, wherein the first inorganic encapsulation layer is in contact with the crack detection part.

7. The display apparatus of claim 1, wherein the dam covers an end of the low-potential power line.

8. The display apparatus of claim 1, wherein the plurality of second structures comprise:
a plurality of first sub-structures; and
a second sub-structure between a first subset of the plurality of first sub-structures and a second subset of the plurality of first sub-structures, and
wherein a height of each of the plurality of first sub-structures is different from a height of the second sub-structure.

9. The display apparatus of claim 8, wherein a height of the dam is greater than the height of each of the plurality of first sub-structures.

10. The display apparatus of claim 1, wherein the low-potential power line comprises a plurality of sub-low-potential power lines that are spaced apart from one another, and the plurality of second structures are on the plurality of sub-low-potential power lines.

11. The display apparatus of claim 10, wherein the first inorganic encapsulation layer is between the plurality of sub-low-potential power lines, and the first inorganic encapsulation layer covers side surfaces of the plurality of sub-low-potential power lines.

12. The display apparatus of claim 1, further comprising:
a spacer on the bank; and
a planarization layer below the light-emitting element,
wherein the first structure includes a same material as the spacer,
wherein the plurality of second structures include a same material as the spacer and the bank, and
wherein the dam includes a same material as the spacer, the bank, and the planarization layer.

13. A display apparatus, comprising:
a substrate comprising a display area and a non-display area, the non-display area surrounding the display area;
a light-emitting element on the substrate in the display area;
a bank on the substrate;
an encapsulation layer on the light-emitting element, the encapsulation layer comprising a first inorganic encapsulation layer, an organic encapsulation layer on the first inorganic encapsulation layer, and a second inorganic encapsulation layer on the organic encapsulation layer;
a low-potential power line outside the bank, the low-potential power line overlapping the organic encapsulation layer in the non-display area;
a first structure on the bank in the non-display area;
a plurality of second structures on the low-potential power line in the non-display area; and
a dam outside the plurality of second structures, the dam surrounding the organic encapsulation layer in the non-display area,
wherein an end of the first inorganic encapsulation layer and an end of the second inorganic encapsulation layer are aligned with an end of the substrate.

14. The display apparatus of claim 13, further comprising:
a crack detection part on the substrate in the non-display area, the crack detection part surrounding the low-potential power line,
wherein the first inorganic encapsulation layer is in contact with the crack detection part.

15. The display apparatus of claim 13, wherein the dam overlaps an end of the low-potential power line.

16. The display apparatus of claim 13, wherein the plurality of second structures comprise a plurality of first sub-structures having a first height and a second sub-structure having a second height that is different from the first height, and the plurality of first sub-structures and the second sub-structure are alternately arranged on the non-display area of the substrate.

17. The display apparatus of claim 16, wherein the second sub-structure includes a first sub-structure of the plurality of first sub-structures and an additional layer on the first sub-structure.

18. The display apparatus of claim 13, wherein the low-potential power line comprises a plurality of sub-low-potential power lines that are spaced apart from one another, and the plurality of sub-low-potential power lines are between the plurality of first sub-structures and the second sub-structure that are spaced apart from one another.

19. The display apparatus of claim 18, wherein the first inorganic encapsulation layer is between the plurality of first sub-structures and the second sub-structure, and the first inorganic encapsulation layer covers side surfaces of the plurality of sub-low-potential power lines.

20. A display apparatus, comprising:
a substrate including a display area and a non-display area;
a light-emitting element on the display area of the substrate;
a dam on the non-display area of the substrate;
a low-potential power line on the non-display area of the substrate;
a plurality of first structures on the low-potential power line in the non-display area and at a first side of the dam; and
an encapsulation layer on the light-emitting element, the encapsulation layer including an organic encapsulation layer that overlaps the plurality of first structures and extends past an end of the plurality of first structures to the dam without extending past an end of the dam.

21. The display apparatus of claim 20, further comprising:
a bank on the display area and the non-display area of the substrate; and
a second structure on the bank in the non-display area, the organic encapsulation layer overlapping the second structure and extending past an end of the second structure,
wherein the plurality of first structures are between the second structure on the bank and the dam.

22. The display apparatus of claim 20, wherein the encapsulation layer further includes a first inorganic encapsulation layer and a second inorganic encapsulation layer where the organic encapsulation layer is between the first inorganic encapsulation layer and the second inorganic encapsulation layer,
wherein the first inorganic encapsulation layer and the third inorganic encapsulation layer overlap the plurality of first structures and the dam and extend past the end of the dam.

23. The display apparatus of claim 22, wherein an end of the first inorganic encapsulation layer and an end of the third inorganic encapsulation layer are aligned with an end of the substrate at a second side of the dam that is opposite to the first side.

24. The display apparatus of claim 22, further comprising:
a crack detection part on the non-display area of the substrate at a second side of the dam that is opposite to the first side,
wherein the first inorganic encapsulation layer and the third inorganic encapsulation layer overlap the crack detection part without the organic encapsulation layer overlapping the crack detection part.

25. The display apparatus of claim 20, wherein the plurality of first structures comprises a first sub-structure and a plurality of second sub-structures, the first sub-structure between a first subset of the plurality of second sub-structures and a second subset of the plurality of second sub-structures.

26. The display apparatus of claim 20, wherein the organic encapsulation layer surrounds each of the plurality of first structures.

27. The display apparatus of claim 20, wherein the low-potential power line comprises a plurality of sub-low-potential power lines that are spaced apart from each other, and the plurality of first structures are on the plurality of sub-low-potential power lines.

28. The display apparatus of claim 27, wherein the encapsulation layer further includes an inorganic encapsulation layer where the organic encapsulation layer is on the inorganic encapsulation layer, the organic encapsulation layer fills a top surface of the inorganic encapsulation layer where the top surface is curved along shapes of the plurality of first structures and along shapes of the plurality of sub-low-potential power lines.

29. The display apparatus of claim 20, wherein a portion of the dam overlaps the low-potential power line.

30. The display apparatus of claim 20, wherein a height of the dam is greater than a height of each of the plurality of structures.
